(19) United States
(12) Patent Application Publication
(10) Pub. No.: US 2024/0210255 A1
(43) Pub. Date: Jun. 27, 2024

(54) TEMPERATURE SENSOR

(71) Applicant: ABLIC Inc., Nagano (JP)

(72) Inventor: Tsutomu TOMIOKA, Nagano (JP)

(73) Assignee: ABLIC Inc., Nagano (JP)

(21) Appl. No.: 18/497,990

(22) Filed: Oct. 30, 2023

(30) Foreign Application Priority Data
Dec. 26, 2022 (JP) 2022-207738

(51) Int. Cl. G01K 7/01

(52) U.S. Cl. CPC G01K 7/01; G01K 2215/00

(57) ABSTRACT

A low-cost and easy-to-use temperature sensor is capable of measuring minute temperature changes. A temperature sensor 1 includes a diode 15 which is a temperature sensing element (PN junction element), a variable current source 10 which supplies at least two different forward currents I1 and I2 to the diode 15, a constant voltage source 16 which outputs a constant voltage Vb having the same temperature properties as a forward voltage Vf of the diode 15 and an amplifier 17 which amplifies a difference between the forward voltage Vf of the diode 15 and the constant voltage Vb.

### CROSS-REFERENCE TO RELATED APPLICATION

This application claims the priority benefits of Japanese application no. 2022-207738, filed on Dec. 26, 2022. The entirety of the above-mentioned patent application is hereby incorporated by reference herein and made a part of this specification.

### BACKGROUND

### Technical Field

The present invention relates to a temperature sensor.

### Description of Related Art

Temperature sensors used in various applications have to accurately measure temperatures. In order to measure the temperature accurately, for example, factors which cause errors are expected to be removed as much as possible, so as not to cause errors in temperature measurement.

FIG. 5 is a circuit diagram illustrating a conventional temperature sensor 500. The temperature sensor 500 obtains a temperature from the difference in forward voltages when forward currents I1 and I2 of different current values are passed through a diode 51, which is a temperature sensing element (see, for example, Patent Literature 1 (U.S. Pat. No. 3,812,717)). According to the temperature sensor 500, the temperature may be obtained from which the influence of variations in a saturation current of the diode 51, which causes errors, is removed.

A voltage difference ΔVo (Vo1−Vo2) output from the temperature sensor 500 is represented by A(kT/q)ln(N). Here, Vo1 is a voltage obtained by amplifying the forward voltage when the forward current I1 is passed through the diode 51 by an amplifier 52; Vo2 is a voltage obtained by amplifying the forward voltage when the forward current I2 is passed through the diode 51 by the amplifier 52; k is the Boltzmann constant; t is an absolute temperature; q is an electronic charge; A is an amplification factor of the amplifier; N is the forward current ratio I1/I2; and ln is the logarithm with Napier's number e as the base, that is, the natural logarithm.

A temperature T is expressed as qΔVo/{kAln(N)}, and a temperature coefficient dΔVo/dT is expressed as dΔVo/dT=A(k/q)×ln(N).

k=1.38×10⁻²³[J/K],q=1.60×10⁻¹⁹[C],

and when N=2, the temperature coefficient dΔVo/dT is about to be A×60[μV/K].

However, if a conventional temperature sensor is configured to measure minute temperature changes, a voltmeter which measures the output voltage of a temperature sensor needs to have a large measurement range and a small resolution.

In the case of measuring a minute temperature change, for example, a temperature change of 0.1K, the temperature coefficient dΔVo/dT is A×6[μV/0.1K]. At this time, in order to obtain a voltage change (temperature coefficient of 600 μV/0.1K) measurable by a general voltmeter such as an IC tester, an amplification factor A of an amplifier has to be set to 100 or more. On the other hand, in the case of forward voltages Vf1 and Vf2 of a diode being about 0.6V at a certain temperature, the output voltage of the amplifier with the amplification factor A of 100 or more is 60V or more.

The present invention is intended to provide a low-cost and easy-to-use temperature sensor capable of measuring minute temperature changes.

### SUMMARY

A temperature sensor according to an aspect of the present invention includes a PN junction element which is a temperature sensing element, a variable current source which supplies different forward currents of at least two values to the PN junction element, a constant voltage source which outputs a constant voltage having the same temperature properties as a forward voltage of the PN junction element, and an amplifier which amplifies a difference between the forward voltage of the PN junction element and the constant voltage.

The present invention may provide a low-cost and easy-to-use temperature sensor capable of measuring minute temperature changes.

### BRIEF DESCRIPTION OF THE DRAWINGS

FIG. 1 is a circuit diagram illustrating a temperature sensor according to an embodiment of the present invention.

FIG. 2 is a graph illustrating temperature properties of forward voltages Vf1 and Vf2 and a constant voltage Vb of the temperature sensor of the present embodiment.

FIG. 3 is a circuit diagram illustrating a first example of the constant voltage source of the temperature sensor of the embodiment.

FIG. 4 is a circuit diagram illustrating a second example of the constant voltage source of the temperature sensor of the embodiment.

FIG. 5 is a circuit diagram illustrating a conventional temperature sensor.

### DESCRIPTION OF THE EMBODIMENTS

A temperature sensor according to an embodiment of the present invention will be described below with reference to the drawings.

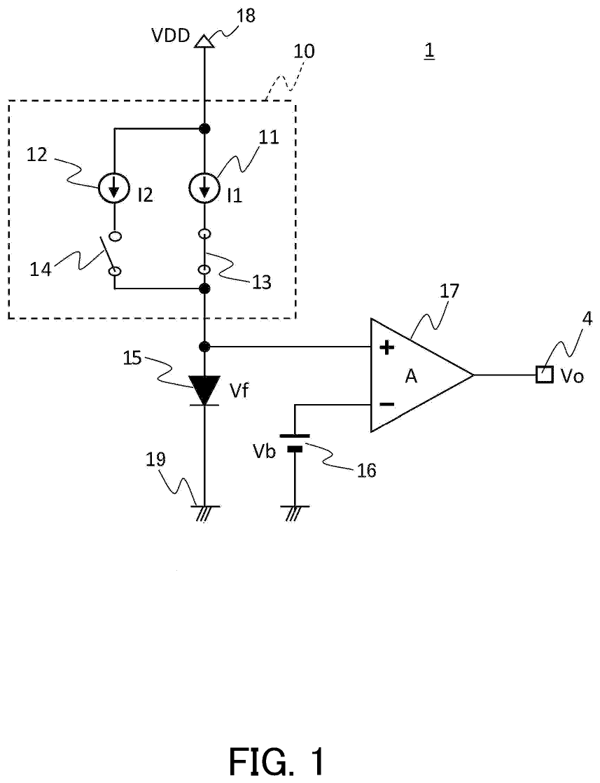

FIG. 1 is a circuit diagram illustrating a temperature sensor 1 according to the embodiment.

The temperature sensor 1 includes constant current sources 11 and 12, switches 13 and 14, a diode 15 configured to be a temperature sensing element, a constant voltage source 16, an amplifier 17 and an output port 4. The constant current sources 11 and 12 and the switches 13 and 14 are configured to constitute a variable current source 10. A power supply terminal 18 is configured to be a power supply voltage supply terminal which supplies a voltage VDD as a power supply voltage. A ground terminal 19 is configured to be a power supply voltage supply terminal which supplies a ground voltage as a power supply voltage different from the voltage VDD.

The constant current source 11 has one end connected to the power supply terminal 18 and the other end connected to one end of the switch 13. The constant current source 12 has one end connected to the power supply terminal 18 and the other end connected to one end of the switch 14. The diode 15 includes an anode connected to the other end of the switch 13, the other end of the switch 14 and a non-inverting input port (+) of the amplifier 17, and a cathode connected to the ground terminal 19. The constant voltage source 16 is an example of the constant voltage source included in the temperature sensor of the embodiment. The constant voltage source 16 has one end connected to an inverting input port (−) of the amplifier 17 and the other end connected to the ground terminal 19. An output port of the amplifier 17 is connected to the output port 4.

The constant voltage source 16 is configured, for example, to output a forward voltage generated in the case where a constant current slightly smaller than constant currents I1 and I2 is passed through a diode of the same type as the diode 15 as a constant voltage Vb. The constant voltage Vb is, for example, a value slightly lower than forward voltages Vf1 and Vf2.

The constant current source 11 outputs the constant current I1. The constant current source 12 outputs the constant current I2 having a current value different from a current value of the constant current I1. The diode 15 generates the forward voltage Vf1 in response to the supply of the constant current I1, and generates the forward voltage Vf2 in response to the supply of the constant current I2 and outputs the forward voltage Vf1 and the forward voltage Vf2 to the non-inverting input port (+) of the amplifier 17. The constant voltage source 16 outputs the constant voltage Vb having the same temperature properties as a forward voltage Vf of the diode 15 to the inverting input port (−) of the amplifier 17. The amplifier 17 outputs an output voltage Vo and transmits the output voltage Vo to the output port 4.

Operation of the temperature sensor 1 will be described.

First, the switch 13 is turned on, the switch 14 is turned off and the constant current I1 of the constant current source 11 is supplied to the diode 15. In the case where the constant current I1 flows through the diode 15 as a forward current, the forward voltage generated in the diode 15 is assumed to be Vf1. The forward voltage Vf1 corresponds to the temperature in the case where the constant current I1 flows through the diode 15.

Next, the switch 13 is turned off, the switch 14 is turned on and the constant current I2 of the constant current source 12 is supplied to the diode 15. In the case where the constant current I2 flows through the diode 15 as a forward current, the forward voltage generated in the diode 15 is assumed to be Vf2. The forward voltage Vf2 corresponds to the temperature in the case where the constant current I2 flows through the diode 15.

The forward voltages Vf1 and Vf2 generated in the diode 15 are input to the non-inverting input port (+) of the amplifier 17. The voltage Vb output from the constant voltage source 16 is input to the inverting input port (−) of the amplifier 17. The amplifier 17 amplifies the difference between the forward voltage Vf1 and the voltage Vb with an amplification factor A, amplifies the difference between the forward voltage Vf2 and the voltage Vb with the amplification factor A and outputs the output voltage Vo. The output voltage Vo output from the amplifier 17 is output to an external device (not illustrated) connected to the output port 4.

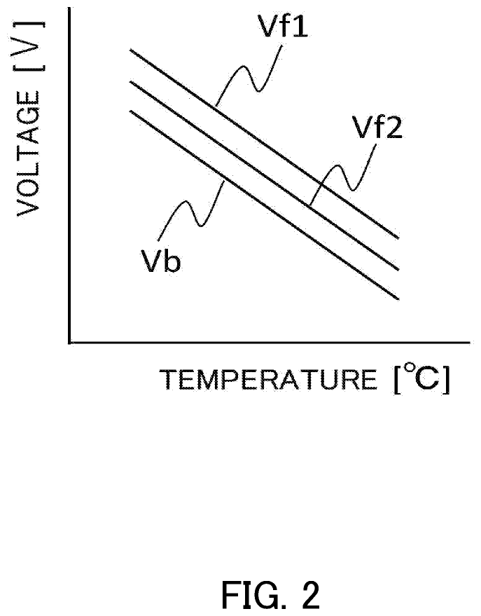

FIG. 2 is a graph illustrating temperature properties of the forward voltages Vf1 and Vf2 and the constant voltage Vb of the temperature sensor 1.

In the embodiment, the relationship between the constant current I1 and the constant current I2 is I1>I2, that is, the relationship between the forward voltage Vf1 and the forward voltage Vf2 is Vf1>Vf2. Since both the forward voltage Vf1 and the forward voltage Vf2 are forward voltages generated in the diode 15, the forward voltage Vf1 and the forward voltage Vf2 have the same temperature properties. The constant voltage Vb has the same temperature properties as the forward voltages Vf1 and Vf2 generated in a circuit of the constant voltage source 16, which will be described later, but is a slightly lower voltage.

Next, a method for obtaining the temperature from the output voltage Vo of the temperature sensor 1 will be described.

The forward voltages Vf1 and Vf2 when the forward currents I1 and I2 flow through the diode 15 and the constant voltage Vb are output to the amplifier 17. The amplifier 17 amplifies the difference between the forward voltage Vf1 and the constant voltage Vb and the difference between the forward voltage Vf2 and the constant voltage Vb with the amplification factor A and outputs the differences respectively. The temperature may be obtained from the differences between the output voltages output from the amplifiers 17 respectively.

The forward voltage Vf in the case of a forward current I being passed through the diode is expressed by the following equation (1).

$$V f = ( kT / q ) \times ln ( I / Is ) \qquad ( 1 )$$

(k is the Boltzmann constant, T is an absolute temperature, q is an electron charge and Is is a saturation current)

From equation (1), the forward voltages Vf1 and Vf2 of the diode are represented by the following equations (2) and (3) respectively.

$$Vf 1 = ( kT / q ) \times ln ( I 1 / Is ) \qquad ( 2 )$$

$$Vf 2 = ( kT / q ) \times ln ( I 2 / Is ) \qquad ( 3 )$$

The difference between the forward voltage Vf1 and the constant voltage Vb and the difference between the forward voltage Vf2 and the constant voltage Vb are amplified by the amplifier with the amplification factor A respectively. The output voltages of the amplifier are represented by the following equations (4) and (5), of which are Vo1 and Vo2 respectively.

$$Vo 1 = A \{ ( kT / q ) \times ln ( I 1 / Is ) - Vb \} \qquad ( 4 )$$

$$Vo 2 = A \{ ( kT / q ) \times ln ( I 2 / Is ) - Vb \} \qquad ( 5 )$$

If the ratio of the forward currents I1 and I2 is N:1, a difference ΔVo between the output voltages of the amplifier is represented by the following equation (6).

$$Δ Vo = Vo 1 - Vo 2 = A ( kT / q ) \times ln ( N ) \qquad ( 6 )$$

According to the equation (6), it can be seen that the term of the constant voltage Vb can be eliminated in addition to the term of the saturation current Is of a diode by taking the difference between the output voltages of the amplifier. Solving the equation (6) for the absolute temperature T, the absolute temperature T is expressed by the following equation (7).

$$T = q \times Δ Vo / \{ A \times k \times ln ( N ) \} \qquad ( 7 )$$

Thus, the temperature may be obtained by measuring the output voltages Vo1 and Vo2 of the amplifier with a voltmeter and using the equation (7).

Further, a temperature coefficient dΔVo/dT may be obtained by differentiating both sides of the equation (7).

$$d Δ Vo / dT = A \times ( k / q ) \times ln ( N ) \qquad ( 8 )$$

If k=1.38×10⁻²³[J/K], q=1.60×10⁻¹⁹[C] and N=2, the temperature coefficient dΔVo/dT is expressed by the following equation from equation (8).

$$d Δ Vo / dT \approx A \times 60 [ μ V / K ] \qquad ( 9 )$$

Here, if a minute temperature change has to be measured, for example, a temperature change of 0.1K, the temperature coefficient is A×6[μV/0.1K] from the equation (9). At this time, the amplification factor A of the amplifier is set to 100 or more so that the voltage change (temperature coefficient of 600 μV/0.1K) is measurable by a general voltmeter such as an IC tester. Here, in the case of the forward voltages Vf1 and Vf2 of the diode being about 0.6V at a certain temperature, the constant voltage Vb is set to 0.594V, and the output voltage of the amplifier with the amplification factor A of 100 is about 0.6V because the difference of 0.006V between the forward voltages Vf1 and Vf2 and the constant voltage Vb is amplified.

As described above, the temperature sensor 1 may accurately measure a minute temperature change (temperature coefficient of 600 μV/0.1K) while the voltage amplified by the amplifier 17 is about 0.6V. The temperature sensor 1 is easy to use because the configuration of a measurement circuit in the latter stage does not become complicated. Moreover, according to the temperature sensor 1, the IC tester used in the inspection process does not need a high performance voltmeter, and manufacturing costs can be lower than the conventional temperature sensor which uses a high performance voltmeter as the IC tester.

Next, the constant voltage source 16 which is a first example and a constant voltage source 16A which is a second example of the constant voltage sources included in the temperature sensor of the embodiment will be described.

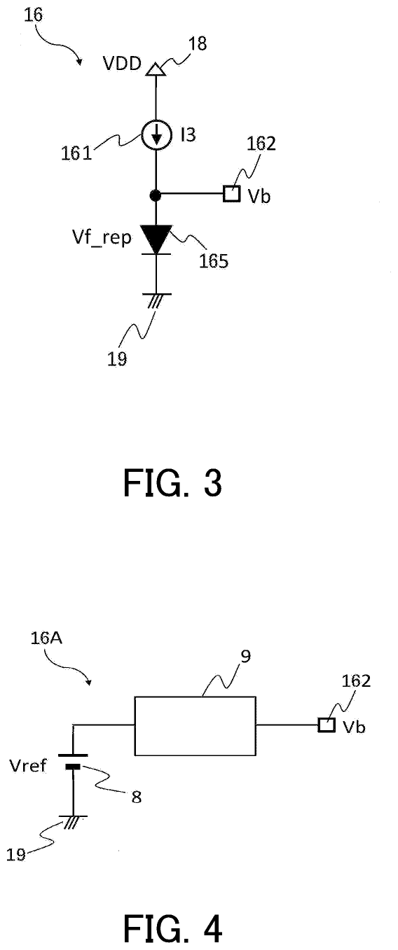

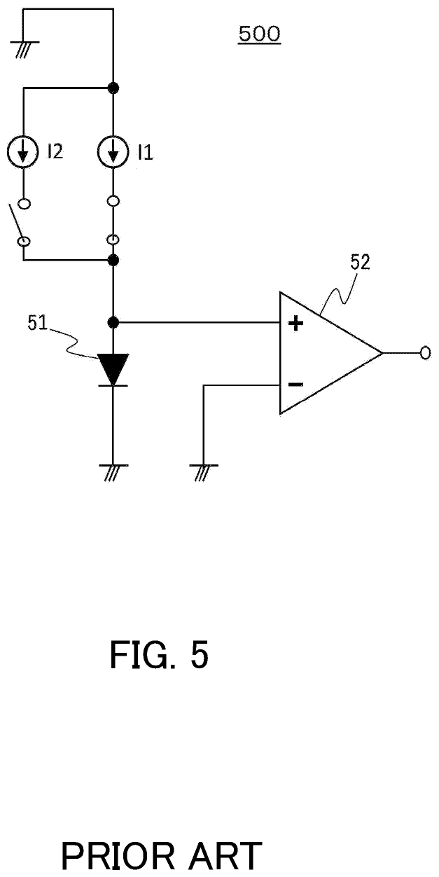

FIG. 3 is a circuit diagram illustrating the circuit configuration of the constant voltage source 16 (first example).
The constant voltage source 16 has a constant current source 161 and a diode 165. A first end of the constant current source 161 is connected to the power supply terminal 18. The diode 165 includes an anode connected to a second end of the constant current source 161 and a cathode connected to the ground terminal 19. A connection point between the constant current source 161 and the diode 165 is connected to an output port 162 of the constant voltage source 16.

The diode 165 has the same temperature properties with respect to the forward voltage as the temperature properties with respect to the forward voltage Vf of the diode 15. The constant current source 161 outputs a constant current I3 in which the constant voltage Vb becomes a voltage value which is slightly lower than the forward voltages Vf1 and Vf2, for example, 0.594V in response to the forward voltages Vf1 and Vf2 being 0.6V. The constant voltage source 16 outputs the constant voltage Vb which is slightly lower than the forward voltages Vf1 and Vf2 and has the same temperature properties as the forward voltages Vf1 and Vf2 of the diode 15.

FIG. 4 is a circuit diagram illustrating the circuit configuration of the constant voltage source 16A (second example).

The constant voltage source 16A includes a reference voltage source 8 and a voltage conversion circuit 9. The reference voltage source 8 is connected between the ground terminal 19 and an input port of the voltage conversion circuit 9. An output port of the reference voltage source 8 is connected to the input port of the voltage conversion circuit 9. An output port of the voltage conversion circuit 9 is connected to the output port 162 of the constant voltage source 16A.

The reference voltage source 8 outputs a reference voltage Vref having the same temperature properties as the forward voltage Vf of the diode 15. The voltage conversion circuit 9 converts the reference voltage Vref into the constant voltage Vb and outputs the constant voltage Vb. The constant voltage Vb is a voltage slightly lower than the forward voltages Vf1 and Vf2. Thus, the constant voltage source 16A outputs the constant voltage Vb which is slightly lower than the forward voltages Vf1 and Vf2 and has the same temperature properties as the forward voltage Vf of the diode 15. The voltage conversion circuit 9 is, for example, a voltage regulator or a DA converter.

Since the constant voltage source 16A includes the voltage conversion circuit 9, the constant voltage Vb may be easily adjusted to a preferable voltage.

Although the embodiments of the present invention have been described above, the present invention is not limited to the embodiments described above. In the implementation stage, implement may be performed in various forms other than the above-described embodiments, and various omissions, additions, replacements, or modifications may be made without departing from the spirit of the invention.

For example, in the embodiments, a diode, which is a temperature sensing element, is described, but the present invention is not limited thereto, and any PN junction element may be used. A PN junction element is a semiconductor element including a contact surface (PN junction) between a P-type semiconductor and an N-type semiconductor, and is not limited to a diode. Also, the forward voltage Vf of the diode as the PN junction element has been described as about 0.6V, and the constant voltage Vb having the same temperature properties as the forward voltage Vf of the diode has been described as 0.594V, but not limited thereto. In addition, different currents of two values supplied to the diode by the variable current source have been described, but not limited thereto, and temperature measurement may be performed by using different currents of three or more values.

Such embodiments and modifications thereof are included in the scope and spirit of the invention, and are also included in the scope of the invention described in the claims and equivalents thereof.

What is claimed is:

1. A temperature sensor, comprising:
a PN junction element, configured to be a temperature sensing element;
a variable current source, configured to supply at least two different forward currents to the PN junction element;
a constant voltage source, configured to output a constant voltage having the same temperature properties as a forward voltage of the PN junction element; and
an amplifier, configured to amplify a difference between the forward voltage of the PN junction element and the constant voltage.

2. The temperature sensor according to claim 1, wherein
the constant voltage source comprises a second PN junction element having the same temperature properties as the PN junction element, and
a constant current source configured to supply a forward current to the second PN junction element,
wherein a forward voltage of the second PN junction element is the constant voltage.

3. The temperature sensor according to claim 1, wherein
the constant voltage source comprises a reference voltage source configured to supply a reference voltage having the same temperature properties as the forward voltage of the PN junction element, and
a voltage conversion circuit configured to convert the reference voltage supplied into the constant voltage and outputting the constant voltage.
